(19) United States
(12) Patent Application Publication
(10) Pub. No.: US 2026/0118453 A1
(43) Pub. Date: Apr. 30, 2026

(54) QUANTUM SENSOR INTERPOSER PACKAGING (QSIP) WITH SMART GRID MONITORING

(71) Applicant: University of Southern California, Los Angeles, CA (US)

(72) Inventors: Ajey Poovannummoottil JACOB, Watervliet, NY (US); Sugeet SUNDER, Los Angeles, CA (US)

(21) Appl. No.: 19/033,302

(22) Filed: Jan. 21, 2025

Related U.S. Application Data
(60) Provisional application No. 63/623,077, filed on Jan. 19, 2024.

(51) Int. Cl. G01R 33/26

(52) U.S. Cl. CPC G01R 33/26

(57) ABSTRACT

Provided is an interposer comprising: one or more photonic waveguide; one or more microwave circuit; one or more optical interconnect; and one or more electronic interconnect, further configured to support a quantum sensor, and methods of operating and fabricating thereof. Further provided is a the interposer containing one or more classical sensors. Further provided is a network of quantum sensors supported by said interposers.

### CROSS-REFERENCE TO RELATED APPLICATIONS

This application claims the benefit of U.S. Provisional Pat. App. 63/623,077, titled QUANTUM SENSOR INTERPOSER PACKAGING (QSIP) FOR SMART GRID MONITORING, filed 19 Jan. 2024, the entire content of which is hereby incorporated by reference.

### BACKGROUND

Management of the current U.S. electrical grid may suffer from at least two significant challenges: aging infrastructure and distributed energy resource (DER) integration. Much of the electrical grid, which may date back to the 1960s and 1970s, relies on components like transformers which may be functioning beyond their designed lifespan, and which may therefore have increased failure risks. The integration of DERs, such as solar, wind, energy storage (e.g., battery), and electric vehicles (EVs) (which may function as both energy stores and energy sinks), may also add complexity to grid management and may necessitate modernization in order to deliver reliability amidst diverse challenges, such as extreme weather and cybersecurity threats. A smart grid model, such as one focusing on decentralized power generation and flexible network designs with bidirectional power flows, may, in some instances, mitigate these challenges. However, sensors for smart grid management (e.g., smart grid sensors) which may provide detailed sensor data (e.g., monitoring data, performance data, transmission information, etc.) over the relatively large distances involved in electrical transmission may be lacking. A national or global coordinated sensor network may be needed to improve grid management and efficiency, and might, in some instances, lead to integration of an advanced early warning system for natural disasters and other threats in the electrical grid.

While the present techniques are susceptible to various modifications and alternative forms, specific embodiments thereof are shown by way of example in the drawings included or described herein. The drawings may not be to-scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims. Further, the description of problems (to be solved, with other techniques, technical problems, etc.) should not be read to imply that all embodiments must fully eliminate those problems, or that any techniques suffering to some degree from such problems are disclaimed, as various inventive techniques are described and various engineering and cost trade-offs may result in only subsets of such problems being mitigated only partially by some embodiments consistent with the present techniques.

### SUMMARY

The following is a non-exhaustive list of some aspects of the present techniques. These and other aspects are described in the following disclosure.

Some aspects include an interposer.

Some aspects include the interposer integrated with one or more sensors, which may include one or more quantum sensors.

Some aspects include a network of interposers, in which the sensors of the interposers may be in communication, including by entanglement.

Some aspects include a method of operating one or more sensors integrated with an interposer.

Some aspects include a method of operating a network of sensors, which may be sensors of a network of interposers.

Some aspects include a method of operating a network of quantum sensors, which may be supported by a network of interposers.

Some aspects include a method of fabricating an interposer, which may include homogeneous or heterogeneous fabrication.

Some aspects include a tangible, non-transitory, machine-readable medium storing instructions that when executed by a data processing apparatus cause the data processing apparatus to perform one or more operations including the above-mentioned aspects.

Some aspects include a system, including: one or more processors; and memory storing instructions that when executed by the processors cause the processors to effectuate one or more operations of the above-mentioned aspects.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 is a schematic representation of an electrical grid system incorporating one or more Quantum Sensor Interposer Packaging (QSIP) platform, in accordance with one or more embodiments;

FIG. 2A is an example energy band diagram for a Nitrogen Vacancy (NV) center is a nanodiamond under applied magnetic field; in accordance with one or more embodiments;

FIG. 2B is a schematic representation of a Remnant Polarization Magnetometer for use with a QSIP platform; in accordance with one or more embodiments;

FIG. 3 is a schematic representation of an example atomic clock for integration in the QSIP platform, in accordance with one or more embodiments;

FIG. 4 is a schematic representation of a cross-sectional view of an example QSIP platform, in accordance with one or more embodiments;

FIG. 5 is a schematic representation of an angle view of an example QSIP platform with chip bonding, in accordance with one or more embodiments, in accordance with one or more embodiments;

FIG. 6A is an example energy band diagram for photons in the NV center; in accordance with one or more embodiments;

FIG. 6B is a schematic diagram for an example quantum Raman sensor and transducer for use with a QSIP platform, in accordance with one or more embodiments;

FIG. 7 is a schematic representation of an atomic clock for qubit synchronization and timing control for use with a QSIP platform, in accordance with one or more embodiments;

FIG. 8A-8B are schematic representations of interfacing between distributed quantum systems for use with a QSIP platform, in accordance with one or more embodiments;

FIG. 9A is a schematic representation of entanglement between two different QSIP platform; in accordance with one or more embodiments;

FIG. 9B is a schematic representation of a quantum sensor network using one or more QSIP platform, in accordance with one or more embodiments; and

FIG. 10 is a schematic representation of an example computing system for use with a QSIP platform, in accordance one or more embodiments.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION

To mitigate the problems described herein, the inventors had to both invent solutions and, in some cases just as importantly, recognize problems overlooked (or not yet foreseen) by others in the fields of quantum computing integration. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

For example, this disclosure refers to specific types of quantum elements (e.g., qubits, NV qubits, quantum repeaters, quantum entanglers, quantum sensors, quantum memory, etc.), specific types of photonic elements (e.g., ring resonators, quantum dots, resonant cavities, waveguides, optical couplers, optical interconnects, photonic crystals, etc.), specify types of opto-electronic elements (e.g., transducer, optical sources, lasers, optical detectors, etc.), specific types of electronic elements (e.g., clocks, atomic clocks, memory, processors, etc.) and specific types of integration elements (e.g., interposers, bump soldering, heat sinks, through silicon vias (TSVs), etc.) in illustrative examples. Aspects of this disclosure can instead be practiced with other or additional types of circuits (e.g., other types of qubits, quantum elements, atomic clocks, etc.) and other types of integration. Further, well-known structures, components, instruction instances, protocols, and techniques may not have been shown in detail in order to not obfuscate the description.

In some embodiments, a heterogeneous integrated Quantum Sensor Interposer Packaging (QSIP) platform may contain quantum and classical sensors, including at least one of each of quantum sensors and classical (e.g., non-quantum) sensors, at least one amplifier and transducer, and clocking components on the same platform, such as for utility grid monitoring.

In some embodiments, the QSIP platform may contain heterogeneously integrated sensing, gain, transduction, circulators, clocking, network, etc. electronics, which may be quantum or classical electronics, on an interposer.

In some embodiments, the QSIP platform may be fabricated of one or more of silicon, silicon dioxide, germanium, gallium arsenide, sapphire, glass, etc.

In some embodiments, circulators (e.g., photonic or microwave circulators) may be on-chip directional circulators containing topological chiral materials.

In some embodiments, the QSIP platform may perform qubit clocking synchronization and timing control (e.g., of qubit sensing) by atom clock. In some embodiments, an atomic clock, such as a Ru atomic clock, may be integrated (e.g., heterogeneously, including by flip-chip bonding, or homogeneously) into the QSIP platform.

In some embodiments, the QSIP may provide heterogeneous integration, such as by co-packaged quantum optics (CPQO)) of multiple qubits and quantum systems, which may be the same or different, including with integrated peripheral circuits (which may be non-quantum systems) and thermal sinks.

In some embodiments, the QSIP platform may provide an integrated platform for quantum sensing.

In some embodiments, the QSIP platform may provide a sensor base for a network of quantum sensors, such as configured for utility (e.g., electrical, water, etc.) grid monitoring.

In some embodiments, quantum sensors may be sensitive to perturbations, including perturbations in one or more of magnetic field, electric field, temperature, location or movement (e.g., for seismographic detection, stress/strain detection, etc.), etc.

In some embodiments, the QSIP platform may contain one or more lasers, such as a gain laser, or other photonic sources. The laser may operate in any appropriate wavelength regime, such as at telecom frequencies, in the near infrared (near IR), near the diamond emission band, in the microwave regime, etc.

In some embodiments, the QSIP platform may include an atomic clock, such as a Cs atomic clock, a Ru atomic clock, etc. The atomic clock may be configured to provide synchronization, including synchronization between quantum computing elements, between quantum and classical computing elements, etc. The atomic clock may operate at any appropriate frequency. The atomic clock may be a miniaturized alkali atomic clock. The atomic clock may provide a substantially stable timing reference. The atomic clock may be integrated, including homogeneously, heterogeneously, etc. into the QSIP platform. The atomic clock may be fabricated in silicon or any other appropriate material. The atomic clock may operate using one or more Micro-Electric-Mechanical (MEMS) system. The atomic clock may include a vapor filled cell, such as containing an alkali material vapor, where vapor may include suspended atoms or molecules below a critical temperature or gas. The atomic clock may contain an optical local oscillator, a vapor cell, one or more micro resonator frequency combs, etc. The atomic clock may contain any appropriate circuitry for clockwork, including optical clockwork.

In some embodiments, the QSIP platform may operate to connect multiple chips (e.g., computer chips, integrated circuits (ICs), etc.). The chips may include one or more electronic (e.g, classical computing) chips, such as electronic memory (e.g., volatile memory, non-volatile memory, RAM, SRAM, DRAM, ROM, etc.), electronic processors (e.g., microcontrollers, quantum controllers, microprocessor, application-specific instruction set processor (ASIP), etc.), etc. The chips may include one or more quantum (e.g., containing wholly or partially quantum computing) chips, such as superconducting qubits, NV diamond qubits, quantum memory circuits, etc. The chips may include one or more modulators, such as a phase modulator (for example, a lithium niobate modulator), which may modulate any appropriate optical, microwave, or other electromagnetic signal. The chips may include one or more microwave chips, such as a microwave transducer, a microwave quantum readout, etc. The chips may include one or more photonic (for example, optical) chips, such as a single photon light source, a laser, a quantum Raman gain laser sensor and transducer, optical detector, etc. The chips may include clocks or clocking signal generator, such as one or more atomic clocks, as previously described. The QSIP platform may include photonic devices, which may be active or passive photonic devices, such as a photonic crystal, photonic waveguide, grating coupler, optical I/O (for example, a backside optical I/O coupler with fiber pig tail, I/O edge coupler, etc.), optical isolation element, etc. The chips may include one or more thermal elements, such as heat sinks, thermal isolation elements, active cooling elements, active heating elements, microfluidic devices, etc. The chips may include one or more mechanical or micro-mechanical, such as micromechanical electrical system (MEMS), devices, which may include microfluidic, pumping, vapor generation, etc. devices.

In some embodiments, one or more chips may be connected to the QSIP platform by heterogeneous integration, such as by soldering, wire bonding, TSVs, flip chip bonding, etc., with or without annealing. In some embodiments, one or more chips may be optically connected to the QSIP platform by one or more optical interconnect, which may be a chiral optical interconnect, backside optical connect, optical pigtail, etc. In some embodiments, one or more chips may be electrically connected to the QSIP platform by one or more electrical connect, which may be a non-reciprocal interconnect.

In some embodiments, the QSIP platform may include one or more qubits (e.g., one or more quantum containers storing one or more qubits). The one or more qubits may be similar (e.g., in the same system or multiple systems with the same configuration) or different (e.g., different types, having different energy levels, etc.). The qubit may be a diamond NV center qubit. The qubit may have any appropriate spin, energy, or other state by which information may be stored. The qubit may be located in (e.g., substantially contained within) a resonator or other quantum well. The qubit may be stimulated by application of one or more photons, such as from a laser photon source, where the photons may be communicated through optical interconnects of the QSIP platform, such as from another region of the QSIP platform or from another chip optically connected to the QSIP platform. The qubit may be sensitive to magnetic field, such as by energy level splitting. The state of the qubit may be measured by any appropriate means, such as optically, in the microwave, etc. The qubit may be entangled with any other appropriate qubit, including through the QSIP platform. The qubit may be entangled with other NV center qubits, via microwave (MW) resonators, etc.

In some embodiments, the QSIP platform may be compact and sensitive (e.g., function as a sensor itself), including to electric current, temperature, etc.

In some embodiments, interposer here may be used with optical coupling elements and methods as described in U.S. patent application Ser. No. 18/430,372, titled “BACKSIDE OPTICAL COUPLER” and filed 1 Feb. 2024, which is hereby incorporated by reference in its entirety.

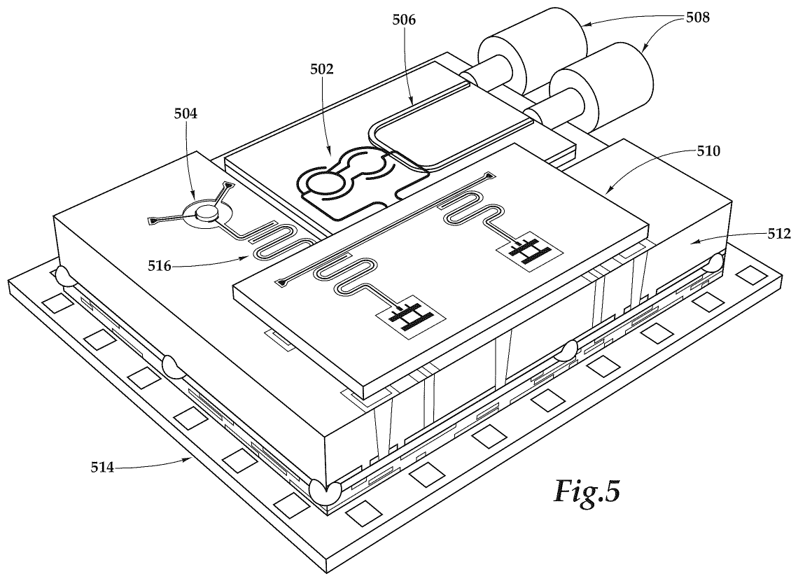

In some embodiments, a monitoring network may be deployed using (e.g., with) the QSIP platform. For example, a room-temperature (or near room-temperature) Quantum Sensor Network (QSN) may be deployed for grid monitoring (including smart grid monitoring), using the QSIP Platform. In some embodiments, the QSIP-based approach may bring advantages associated with quantum sensors, such as enhanced sensitivity and resilience, to monitoring, where increased monitoring capabilities may be expected to enhance a monitoring network and the responsiveness of the monitored/controlled network (for example, for a smart grid, the QSIP-based approach may be expected to boost grid reliability and adaptability). As will be discussed in reference to FIG. 5, in some embodiments the QSIP platform may have a heterogeneously integrated quantum sensor network design.

In some embodiments, the QSIP platform may contain one or more NV quantum Raman gain lasers with an integrated sensor and a transducer, one or more chiral circulator, one or more photonic interconnect, which may include waveguide(s), metamaterial coupler(s), etc., a fiber input/output (I/O), an atomic clock, such as a flip-chip bonded atomic clock, or other element for clocking, a silicon, silicon dioxide, sapphire, etc. interposer which may connect at least some of the other components, and a printed circuit board (PCB) or other circuit with microwave circuitry. Electrical circuitry to control the quantum circuitry, memory, processors, etc. may also be incorporated in the QSIP platform.

In some embodiments, the QSIP platform may be a heterogeneously integrated, scalable interposer packaging architecture with a directional quantum interlinkage, which may merge functionalities within a chip while maintaining qubit coherence. The QSIP platform may be or include elements from a Quantum Interposer Packaging (QuIP) design. In some embodiment, the QSIP platform may enhance the interconnect ecosystem by optimizing power, performance, area, mechanical stability, and integration of thermal dissipating materials. This design may also accommodate multiple power domains and test capabilities.

In some embodiments, the QSIP platform may provide for integration of components into a multifunctional quantum sensor system, which may include isolation materials, materials engineering which may enhance coherence times, electrical field control mechanisms for NV center diamond sensors, which may operate to minimize noise and maximize (e.g., increase) sensing accuracy, integrated (e.g., homogeneously, heterogeneously, etc.) photonic structures which may enhance optical properties, qubit readout fidelity, noise isolation, etc., chip-scale optical isolation (including using two dimensional (2D) material), integration of quantum error correction (e.g., in memory, in processing, in readout, etc.), generation and distribution of quantum entanglement, including through the use of Quantum Key Distribution (QKD), fiber-optic integration (including the use of one or more couplers between waveguides and fibers) for networking, etc. In some embodiments, the interposer may be fabricated of silicon, silicon dioxide, glass or other amorphous (e.g., non-crystalline) materials, diamond, sapphire, etc. in part or in full. In some embodiments, the interposer may be fabricated of optically opaque materials. In some embodiments, the QSIP platform may be fabricated using nano-fabrication techniques, which may include self-assembled materials. In some embodiments, the QSIP platform may be fabricated of multiple diverse materials or units, including those connected through chip-to-chip bonding, flip chip bonding, optical interconnects, electrical interconnects, soldering, wire bonding, etc. In some embodiments, the QSIP platform may bridge the gap between laboratory demonstrations and scalable quantum applications, and may include features configured to allow for a modular quantum system.

In some embodiments, patterning, integration, and assembly complexities may increase as more quantum sensors are added. In some embodiments, the QSIP platform may provide thermal or electromagnetic isolation for one or more sensors, including from each other, from outside thermal or electromagnetic sources, etc. In some embodiments, the QSIP platform may provide packaging for optical and electrical I/O, both to the platform and between elements of the platform. In some embodiments, silicon (which may include crystalline silicon, amorphous silicon, doped silicon dioxide, doped silicon, silicon allows, etc.) may be used for QSIP platform fabrication. Silicon may provide design advantages such as a well-characterized fabrication processes and low microwave dielectric loss, which may provide electromagnetic interference isolation. In some embodiments, for interconnection of between one or more components, chiral (e.g., directionally dependent or nonreciprocal) interconnects may be used, including for both electrical and optical interconnects. In some embodiments, for low temperature electric and microwave interconnects, dissipation-less chiral quantum anomalous Hall insulators may be used for electrical signals to Ru atomic clocks (or other microwave sources/elements). In some embodiments, for microwave interconnects at room temperature, reciprocal elements which contain Yttrium Iron Garnet (YIG) may be used to minimize the reflected noises. Likewise, for optical interconnects, in some embodiments, chiral photonic crystals (which may be fabricated using the concept of quantum anomalous Hall effect to pattern a photonic crystal with a ferromagnetic insulator such as YIG) may be used so that optical transport may occurs with minimized noise, such as from external or reflected sources. In some embodiments, based on the above materials, the QSIP platform may integrate (e.g., fabricate) quantum devices, such as diamond NV sensors and atomic clocks, onto silicon substrates. In some embodiments, the QSIP platform may include heterogeneous integration of such elements, such as through processes like Through-Silicon Vias (TSVs) fabrication and bonding techniques, such as electrostatic or metal-to-metal fusion bonding. In some embodiments, integration of elements into the QSIP platform may involve wire bonding, fiber connections, and (fiber) housing(s), which may provide for thermal and electromagnetic shielding.

In some embodiments, the QSIP platform may combine various quantum devices, such as diamond NV centers, Ce or Ru atomic clocks, single-photon sources, etc. while providing thermal and operation integrity, including between such devices.

In some embodiments, the QSIP platform may provide thermal isolation, which may stabilize quantum states while also providing mechanical integrity. In some embodiments, the QSIP platform may operate at room temperature, near room temperature, above room temperature, etc. In some embodiments, the QSIP platform may contain integrated heating (e.g., electrical or resistive, quantum, etc.) or cooling (e.g., passive cooling, active cooling, heat dissipation, thermoelectric cooling (such as Peltier coolers), etc.). In some embodiments, the QSIP platform may provide thermal control, including through proportional-integral-derivative (PID) or any portion thereof or any other control system operation of both heating and cooling devices.

In some embodiments, the QSIP platform may provide low-loss optical interconnects, such as between elements, to the platform itself, etc. In some embodiments, the QSIP platform may provide quantum clock synchronization between elements or signals of the interposer. For example, the QSIP platform may allow efficient communication and synchronization between NV center qubits, transducers, atomic clocks, photon sources, etc.

In some embodiments, the QSIP platform may be fabricated using microfabrication, including as a dense 2.5D/3D integration, which may allow for construction of multi-qubit arrays and distributed entanglement. In some embodiments, the QSIP platform may include vertical interconnect, such as for layering quantum circuits while maintaining quantum coherence.

In some embodiments, the QSIP platform may integrate interconnects within the interposer which preserve coherence and entanglement. In some embodiments, the QSIP platform may allow efficient performance, even for multi-layered processors.

None of the above is to imply that all embodiments must fully eliminate those problems, or that any techniques suffering to some degree from such problems are disclaimed, as various inventive techniques are described and various engineering and cost trade-offs may result in only subsets of such problems being mitigated only partially by some embodiments consistent with the present techniques.

In some embodiments, the QSIP, such as together with one or more power sources or power loads, may operate to address at least two major U.S. electrical grid challenges: aging infrastructure and distributed energy resource (DER) integration. Much of the grid, which may date back to the 1960s and 1970s, may rely on components like transformers operating beyond their designed lifespan, which may increase both component and grid failure risks. The integration of DERs, such as solar generation, wind generation, energy storage (e.g., battery, pumped water, other energy stores, etc.), and electric vehicles (EVs) (which may be both energy sinks and energy stores), may add complexity and necessitate grid modernization for reliability, especially amidst diverse challenges like extreme weather, cybersecurity threats, etc. In some embodiments, a QSIP platform may allow for a smart grid model, which may focus on decentralized power generation and flexible network designs, which may include bidirectional power flows. In some embodiments, a smart grid model may include a global coordinated sensor network, which may improve grid management and efficiency, and potentially lead to an advanced early warning system for detection and response to natural disasters and other threats.

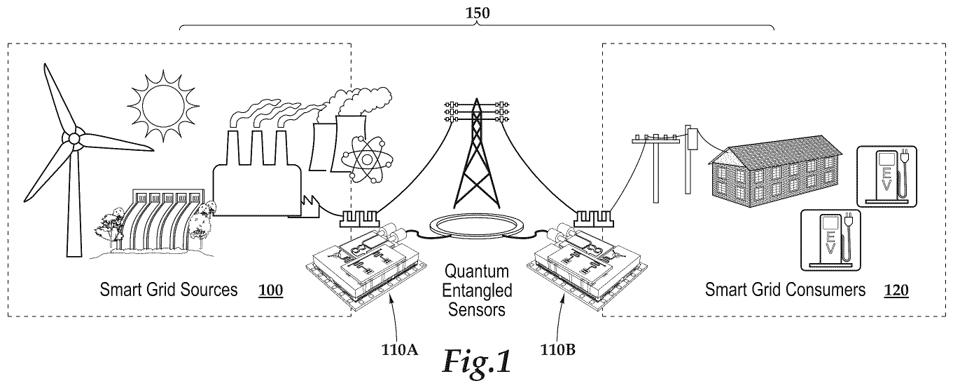

FIG. 1 is a schematic representation of an electrical grid system 150 incorporating one or more Quantum Sensor Interposer Packaging (QSIP) platform 110A, 110B. The electrical grid system may include one or more smart grid source(s) 100, which may include conventional sources, such as hydroelectric, nuclear, natural gas, coal, etc., and one or more distributed energy resources, such as wind, solar, battery backup, etc. Conventional sources may include both sources with consistent output, for example nuclear sources, and sources which short-response times and variable output, such as natural gas generators. The QSIP platform 110A, 110B may include one or more quantum entangled sensors. For example, quantum sensors from the QSIP platform 110A may be entangled with other quantum sensors in the same of a different platform (e.g., QSIP platform 110B), including over optical, electrical, microwave, etc. transmission lines. The electrical grid system may also include one or more smart grid consumer(s) 120, or loads. Smart grid consumers 120 may include distributed power storage systems (e.g., home batteries, electric vehicle (EV) batteries, smart appliances, etc.). The smart grid consumers 120 may include devices, for example, clothes washers, which may be able to account for and respond to, such as by scheduling operations, energy demands or energy prices. For example, a clothes washer may be loaded but wait to perform a washing load overnight until electricity cost drop below a pre-set threshold. The QSIP platform 110A, 110B may provide sensing, monitoring, etc. for various parts of the electrical grid system 150.

In some embodiments, the QSIP platform may be used to advance smart grid functionalities through quantum technology. In some embodiments, a quantum sensing network, using with diamond-NV center qubits and other advanced components, may be established to target enhanced precision, speed, and sensitivity for real-time grid analytics and threat detection. In some embodiments, this may mark a significant step towards innovations in quantum computing and networking. In some embodiments, quantum sensors from diverse fields such as electronics, material science, and photonics, may be integrated into the QSIP platform or a QSIP platform-based grid.

In some embodiments, a quantum network for distributed sensing in using the QSIP platform may involve three components: (1) entanglement-based quantum networks with distillation protocols developed to allow for high-fidelity entangled photon pairs, which may be used alongside quantum error correction (e.g., for network integrity); (2) classical communication protocols utilizing super-dense coding for secure and fast data sharing among nodes, which may allow for real-time analytics for diagnostics and interventions; (3) distributed and integrated quantum sensing, which may employ entangled quantum sensors network-wide for efficient and secure joint state analysis through entanglement. In some embodiments, the QSIP platform may be useful in various ways (e.g., use-cases) and to various stakeholders. Thile in some embodiments, the QSIP platform may be designed to address the unique requirements of the energy sector and to adeptly respond to grid challenges, other industries and application may benefit from QSIP integration.

For example, grid Operators and utilities may be able to leverage quantum sensors to enhance the monitoring and management of the electrical (or other utility) grid. This may include real-time detection of faults, identification of grid congestion, and improvement of grid stability. In another example, energy companies or the energy industry at large may be able to use quantum sensors to optimize energy distribution, reduce losses, and improve the efficiency of renewable energy integration into the grid. In yet another example, researchers into quantum technology, physics, and electrical engineering (including academic and industrial researchers) may benefit from access to advanced quantum sensors for fundamental research and innovation in grid monitoring and other applications. In another example, government agencies responsible for energy regulation, national security, and critical infrastructure protection may use quantum sensors to ensure the resilience and security of the electrical grid. In an example, technology providers and companies specializing in sensor technology, quantum computing, and telecommunications may collaborate to develop and commercialize quantum sensor solutions for a broader market, where quantum sensors from different manufacturers or based in different technology, substrates, nodes, etc. may be integrated through the QSIP platform. In yet another example, the general public may benefit from a more reliable and efficient electrical grid, which may lead to improved energy access, reduced environmental impact, and lower energy costs.

Traditional sensors for magnetic fields, current, and temperature, such as Hall effect, magneto-resistive, and fluxgate sensors, along with current transformers and thermocouples, may face limitations in accuracy, sensitivity, and scalability. The QSIP platform may, in some embodiments, introduce diamond-NV-center sensors, which may represent a major advancement in grid monitoring. These quantum sensors may provide superior precision, rapid response, and enhanced environmental resilience, significantly outperforming conventional technologies. In some embodiments, NV-center-based quantum sensors may have specific advantages over traditional sensors. For example, as magnetic field sensors, NV-center-based quantum sensors may have broad operational temperature range, wide bandwidth, less noise susceptibility, little or no signal degradation, temperature stability, compact size, broader frequency response, lower power consumption, no output integration required, etc., such as when compared to traditional magnetic field sensors. In another example, as electric field sensors, NV-center-based quantum sensors, may have no saturation, no phase shift errors, no high voltage risks, no integrator circuit, no power losses, no heating issues, no external magnetic interference, no light source needed, less calibration required, temperature stability, cost-effectiveness, etc. such as when compared to traditional electric field sensors. In yet another example, as temperature sensors, NV-center-based quantum sensors may have fast and precise readings, no self-heating, no reference or calibration needed, higher accuracy, stability, broad range, consistent readings, no interference, potential lower cost, no reflection issues, robustness against strains and deformations, etc., such as when compared to traditional temperature sensors.

In another example, QSIP platform integration may be capable of transducing various electromagnetic signals (including energy or power transferring signals) to communication wavelength (e.g., fiber optic data communication wavelength), and synchronize clock(s), which may provide many possibilities for integration in a smart grid quantum networking In some embodiments, QSIP platform may transform grid monitoring by applying quantum technology's efficiency, precision, and resilience, which may boost grid reliability and adaptability. A heterogeneously integrated quantum sensor network design for the QSIP will be discussed in reference to FIG. 5. Various components have been designed to enable use of the QSIP and deployment to a smart grid. For example, quantum sensing components have been developed which may demonstrate the capabilities of quantum sensors, quantum gain lasers, quantum transduction mechanisms, and atomic clocks useful for synchronization within the quantum network. -In another example, quantum networking components and algorithms have been developed which may provide useful for integrating and operationalizing quantum data within grid infrastructures. In yet another example, heterogeneous integration of various components on an interposer has been developed, which may include demonstration of cohesive functionality. In another example, the adaptability and applicability of the assembled quantum systems has been validated within real-world grid environments, showcasing the practical benefits of various quantum applications.

### Quantum Components

Classical sensors, which may be used in smart grids such as Rogowski coils. Hall effect sensors, etc., may be limited in sensitivity and interference robustness, which may hinder their real-time monitoring effectiveness. Quantum sensors, including superconducting quantum interference devices (SQUIDs), optical magnetometers, etc., may, such provide enhanced sensitivity and precision but may face integration challenges for use in smart grids and may often function most efficiently with cryogenic conditions or heating for optimal performance. In some embodiments, NV centers in nanodiamonds present a promising solid-state solution for quantum sensing and communication, which may have advantages over some other quantum sensors. These NV centers may exhibit stable electronic properties under varying environmental conditions and maintain a higher signal-to-noise ratio (SNR) than other (quantum) systems across various temperature ranges.

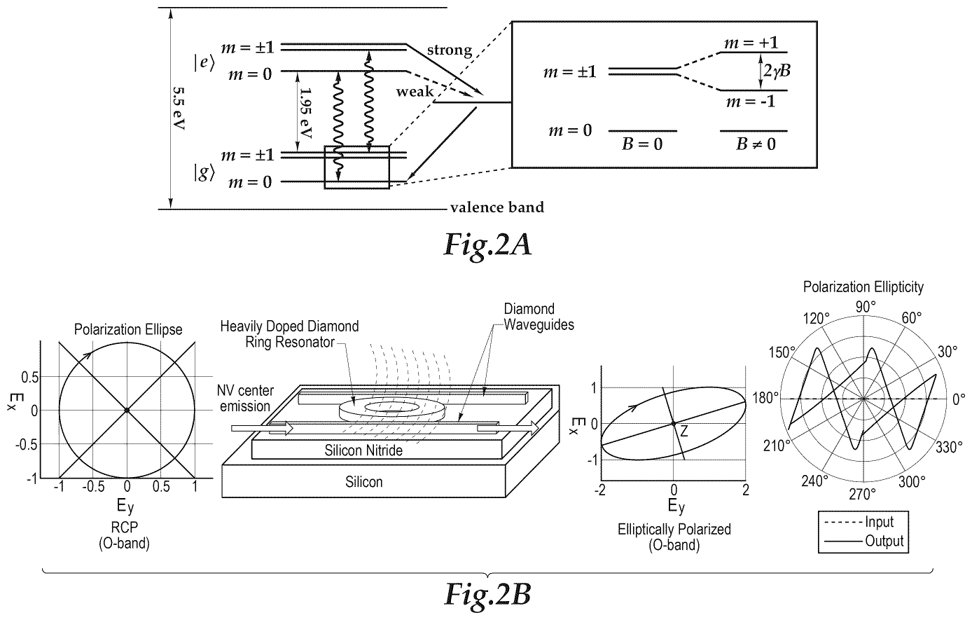

While NV centers may degrade at temperatures above 600K, such temperatures may be unlikely to be reached by sensors on the grid. FIG. 2A is an example energy band diagram for a Nitrogen Vacancy (NV) center is a nanodiamond under applied magnetic field. As shown in FIG. 2A, for NV centers within the diamond band gap, the ground state, which is represented by |g [symbol] , while the excited stat may be represented by |e [symbol] , may be split into a spin singlet and doublet, such as at 2.88 GHz. Radiative transitions may exist between the ground and excited states, both strong and weak non-radiative transitions through the singlet state (e.g., in the band gap) also existing. An external field along the NV axis, e.g., B as depicted in FIG. 2A, may induce a Zeeman shift by splitting the degenerate |±1 [symbol] levels in to two spin sublevels: |+1 [symbol] and |−1 [symbol] , which are depicted in FIG. 2A. The spin sublevels may be separated by an energy ΔE=2γB, as shown in FIG. 2A, where γ=2.803×10⁴ MHz/T is the electron gyromagnetic ratio. The effective spin-Hamiltonian that describes the NV center oriented along k^{th} crystallographic direction in an ensemble at the ground state under temperature and applied homogeneous electric and magnetic field may be given by

$${H}_{k} = D ( {S}_{z , k}^{2} - 2 / 3 ) + γ B \cdot {S}_{k} + {V}_{gs}$$

where V_{gs} is related to the stress and electric field in the material, and S_{z,k} is the spin components along z axis in the k^{th} NV center. The eigenvalues of Hₖ:f_{±}=D+M_{z,k}±Δ, where

$$Δ = \sqrt{{( γ {B}_{z} )}^{2} + {M}_{x , k}^{2} + {M}_{y , k}^{2}}$$

and M_{i,k} are stress parameters, which may give the resonances frequencies that shift the zero-field energy as well as split the spin levels for |±1 [symbol] . The transverse electric field split spin sublevels could range from a few Hz to several MHz depending upon the sample or the embodiment.

In some embodiments, a quantum photonic platform may be tailored for smart grid demands. For example, in some embodiments, the QSIP platform may merge NV centers' magnetic field sensitivity with room-temperature operation and photonic integration. Various embodiments may feature one or more quantum monitoring solutions, such as optically detected magnetic resonance (ODMR), remnant polarization magnetometry (RPM), or any other appropriate quantum monitoring scheme. RPM may include a technique wherein the polarization ellipticity of remnant light is used to detect the applied magnetic field. ODMR may require down-converting emission from a diamond (e.g., or nanodiamond) from 637-850 nm to communication wavelengths (e.g., in the range 1330-1550 nm), while RPM may enable NV-center-based detection within the communication band for seamless grid integration.

FIG. 2B is a schematic representation of a Remnant Polarization Magnetometer for use with a QSIP platform. FIG. 2B depicts right circularly polarized (RCP) input and elliptically polarized output for a RPM. The input may be provided to the heavily doped diamond ring resonator, which may contain an NV center, along a diamond waveguide. The ring resonator and waveguides may be fabricated on silicon nitride on silicon (as depicted in FIG. 2B) or any other appropriate substrate. The interaction of the RCP input with the NV center may create the ellipticity in the output. FIG. 2B also depicts, on a polarization graph, the different between the input and output polarization. From such a relationship, the applied magnetic field may be determined, where the output polarization is a function of the applied magnetic field.

In some embodiments, the integrated photonic platform for quantum sensing (e.g., the QSIP), such as depicted in FIG. 2B or FIG. 5, may use a micro ring resonator with diamond NV centers and may interface with Si, SiN, or another appropriate material waveguides for telecom wavelength inputs and outputs. The RPM may maintains telecom wavelength, while ODMR may adapt (e.g., wavelength shift) visible light to these communication wavelengths. In some embodiments, Raman laser sensing may leverage the Purcell effect in an optical cavity with a ring resonator, and may be focused on the diamond's zero-phonon line (ZPL) at 637 nm. The ZPL may be aligned with the second harmonic generation (SHG) wavelength, for increased efficiency of Raman lasing at the cavity's resonance frequency.

Second Harmonic Generation: In some embodiments, a SHG photon may induce stimulated emission of NV-centers, which may produce an efficient and controlled photon generation mechanism. By combining laser threshold magnetometry with the Purcell effect within an optical cavity, and by leveraging the polarization of light, sensitivity may be boosted—which may represent an improvement in magnetic field detection technology. In some embodiments, this enhanced sensitivity may be quantifiable by the SHG efficiency equation given by:

$${η}_{SHG} = \frac{{χ}^{( 2 )} {I}_{ex}^{2} L}{2 {n}_{2 ω} c {λ}_{ex}} ,$$

where Iₑₓ is the intensity of the coupled O-band light with a wavelength λₑₓ, L corresponds to the circumference of the resonator (e.g., the interaction length of the nonlinear medium), n_{2ω} indicates the refractive index at the second harmonic wavelength, and c represents the speed of light in vacuum. The doping concentration may impact the value of χ⁽²⁾ and be determined experimentally.

Enhanced Sensing by Stimulated Emission: In some embodiments, under steady-state condition, an externally applied transverse magnetic field Bₓ may lead to a reduction in the excited state population ρₑ and the number of photons n resulting from reduced emission of the NV centers into the optical cavity when Bₓ≠0, such as reduced in comparison to the scenario where Bₓ=0. This reduction in population may arise from the mixing of spin states mₛ=0, ±1, where the electron spin operator may interact with the external magnetic field affecting the electronic-spin Hamiltonian [symbol] ∝γ_{NV}\vec{B}·\hat{\vec{S}}, where γ_{NV} represents the gyromagnetic ratio, \vec{B} is the applied magnetic field and [symbol] is the electron spin operator. This may imply that under the influence of an external magnetic field, the rate of stimulated emission reduces as (Γₛₜ ⬇)∝(ρₑ ⬇)G(n ⬇). The cavity-NV center coupling constant G may scale this effect in a cavity. This nonlinear behavior, which may be accentuated by the properties of the lasing cavity, may play a crucial role in enhancing the contrast of the optical process. The SHG emission may have a polarization dependence which extends to the stimulated emission and may therefore be reflected in the magnetic field sensing.

In some embodiments, RPM may use input light polarization to detect magnetic field changes, thereby eliminating the need for converting diamond emissions to telecom wavelengths. Free from O-band light's ellipticity noise, RPM may be more efficient than traditional ODMR spectroscopy and well-suited for optical fiber integration due to its independence from conversion efficiency and photon count constraints. While RPM stands out for its noise immunity and simplicity, ODMR may be advantageous for quantum entanglement, which is vital for quantum computing and communications, through single-photon qubits and entangled photon pair generation. In some embodiments, both single and polycrystalline diamonds may be used to form quantum sensors, where different advantages—which may be used in different embodiments—may be conferred by single crystalline diamond's precise bonding and polycrystalline diamond's versatility for fabricating essential components like waveguides and ring resonators.

Temperature monitoring in power grids may be critical, especially for transformers, such as to preempt failures and inefficiencies. In some embodiments, diamond NV quantum sensors, such as integrated with the QSIP platform may be deployed for this purpose. These sensors may provide millikelvin precision over a wide temperature range, offering accurate monitoring in diverse conditions. Compact and weather-resistant, they may ensure non-intrusive, stable monitoring and are may be appropriate for various, diverse grid locations. In some embodiments, integrating these sensors into the grid may enhance fault detection, improve load management, and prolong component lifespan.

### Atom Clock Synchronization and Networking

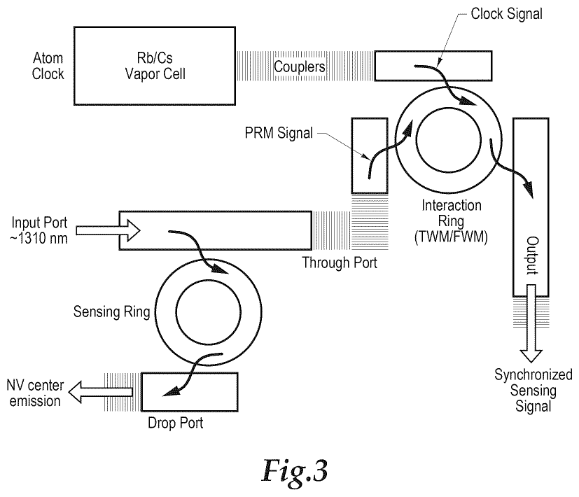

In some embodiments, rubidium (Rb) atomic clocks may be combined with NV center-based quantum sensors, such as to enhance time synchronization in smart grids. In some embodiments, such an integration may help address challenges associated with coordinating distributed energy resources for grid stability. NV sensors, such as those sensitive to magnetic fields, may require precise timing for effective grid monitoring. Traditional synchronization methods like global positioning system (GPS) synchronization may face limitations such as vulnerability to signal blockage and network delays. In some embodiments, the QSIP approach may integrate miniaturized alkali (e.g., Rb) atomic clocks within the sensor network to provide a stable timing reference, which may ensure grid-wide synchronization and quantum coherence. In some embodiments, integration (e.g., of an atomic clock) on the QSIP platform (for example, as depicted in FIG. 3) may merge space-efficient design with simplified quantum network establishment. In some embodiments, Ramsey-Nouvo-Holstein (RNH) techniques may be used, such as together with microfabricated components for clock precision, and then paired with NV sensors through integrated waveguides and phase-locked loops, which may improve synchronization and sensitivity (such as versus conventional clocking methods).

FIG. 3 is a schematic representation of an example atomic clock for integration in the QSIP platform. The atomic clock may contain a vapor cell, such as a Rb or Cs or any other appropriate vapor molecule cell. The vapor cell may include heater or other vaporization elements, such as to maintain the presence of vapor in the vapor cell. The vapor cell may be coupled, such as by one or more optical couplers or other coupling element to a waveguide. The frequency or wavelength of the atomic clock may be any appropriate frequency or wavelength, such as determined by the element contained within the vapor cell or any other configuration of the atomic clock. As depicted in FIG. 3, a signal from the atomic clock, which may be a clock signal, may be optically coupled with an interaction ring (e.g., a two wave mixing (TWM), four wave mixing (FWM), or any other appropriate mixing resonator), for interaction with RPM signals (or other magnetic measurement signals). The output of the interaction ring may be provided to synchronize one or more sensing signal, such as for the RPM of other elements of the QSIP. FIG. 3 also depicts an input port for an input signal, such as an RCP input to the NV center as described in reference to FIG. 2B, and a sensing ring which may contain an NV center. The sensing ring may be optically coupled to both an inport port and drop port, with the RPM signal generated by the drop port signal or pass through of the input port signal. Any appropriate waveguides, resonators, and couplers may be used. The atomic clock may be integrated using non-linear frequency conversion.

In some embodiments, miniaturizing atomic clocks may be fabricated using micro-electro-mechanical systems (MEMS), which may provide for seamless QSIP integration, and may overcome traditional fabrication challenges. In some embodiments, a wafer-level process may be used to fabricate cesium (Cs) or Rb-filled vapor cells using low-temperature techniques, which may reduce residual gases and enhance cell stability. In some embodiments, an atomic clock or associated QSIP design may include heaters, isolators, an on-chip Cs/Rb dispensing component, etc., which may provide an advantage for QSIP-based integration. In some embodiments, the QSIP platform provides for time synchronization with integrated chips, while accounting for miniaturization impacts on clock stability and balancing that with sensor sensitivity optimization.

### Quantum Networking and Algorithms

The power grid may be a networked heterogeneous dynamical system that demonstrates significant emergent behavior and is susceptible to targeted attacks as well as natural failures that can bring down the entire grid system in a cascaded fashion. The state of the network may be represented as a spatiotemporal dynamic sequence, such as given by X(t)∈ [symbol] , where N=S*M and where S is the number of measurement stations or nodes, and M is the number of metrics being measured at each node. X(t) may have significant correlation structures—that is, among the key metrics at a node, as well as among the metrics across the nodes—that may be time-varying. The statistics of these state variables may be used to perform decentralized load balancing to utilize and mitigate the effects of spatiotemporal fluctuations by optimally connecting demand nodes with supply nodes. In some embodiments, these statistics may also be used for detecting and anticipating anomalies—such as attacks and failures of key components. Global-scale events, such as electromagnetic storms or electromagnetic pulse (EMP) attacks on the power grid, may affect the entire grid (or a significant portion thereof) simultaneously, which may be detected more quickly through correlated measurements. Electromagnetic attacks or EMPs affecting the power grid may involve three components (e.g., divided into E1, E2, E3 effects), each with distinct durations, magnitudes, and frequency ranges. E1 may be characterized by nanosecond durations and high-intensity effects, E2 may resemble lightning impacts and affects systems vulnerable to lightning, while E3, may be the slowest and induce currents in long conductors like transmission lines. Some previous studies may have shown that these components may cause voltage spikes and current surges in transformers, where variations in impact are based on factors like EMP source height and power line configuration, where such effects may potentially exceeding a power grid equipment's protection threshold(s).

While some currently available software and hardware solutions exist for grid monitoring and security, many lack a capability for real-time monitoring of correlated grid events. In some embodiments, is the QSIP platform may provide for a quantum network with entangled NV centers using photons, which may enable precise power grid monitoring and early warning system development against threats, such as may not be available through other or classical technology. The QSIP network may provide, in one or more embodiments, the following:

Entanglement-based quantum networks with distillation protocols: In some embodiments, implementation of the QSIP network may involve creation of an entanglement-based network using shared entangled photons and implementation of entanglement distillation for high-purity states from noisy entangled ensembles. In some embodiments, this may operate based on quantum memory.

Secure and fast classical communication protocols: In some embodiments, the QSIP network may establish entanglement which may enable secure communication of crucial data like sensor measurements to central or network hubs using super-dense coding. In some embodiments, this communication approach may ensure rapid, real-time strategy implementation and response.

Distributed and integrated quantum sensing: In some embodiments correlations in spatiotemporal dynamics captured by sensors may be critical in managing and securing the power grid. In some embodiments, by encoding this classical data into quantum states, it may become accessible only through joint measurements on the entire system, which may ensure local security. In some embodiments, the QSIP platform may provide one or more of the following operations: 1) entangle NV centers with photons transmitted via a fiber optic network, which may leverage entanglement to elucidate grid correlations and dynamics. 2) operate based on pairs of entangled atom-photon systems. For example, for atoms A and B, and photons 1 and 2, the initial state may be given by |Ψ [symbol] ₜₒₜₐₗ=|Ψ [symbol] _{A1}⊗|Ψ [symbol] _{B2}, with |Ψ [symbol] _{A1}=(1/\sqrt{2})(|e [symbol] _{A}|1 [symbol] ₚₕₒₜₒₙ₁|g [symbol] _{A}|0 [symbol] ₚₕₒₜₒₙ₁) and similarly for B2. 3) further, by projecting photons 1 and 2 onto the Bell state |Φ⁺ [symbol] _{photon1,photon2}, atoms A and B may be entangled. The atoms would then be in the Bell state |Φ [symbol] _{AB}=(½)(|e [symbol] _{A}|e [symbol] _{B}+|g [symbol] _{A}|g [symbol] _{B}), which may be fully entangled. 4) in some embodiments, this may be scaled to N atoms and photons, which may create a Greenberger-Horne-Zeilinger (GHZ) state across the network. In some embodiments, this may allow for the use of quantum correlations to monitor the power grid's state, with at least some applications, such as detecting current anomalies and operational faults, occurring in real-time. 5) in some embodiments, for measuring GHZ states in atomic ensembles, collective measurements involving unitary transformations and detection of atomic states may be used. These sophisticated techniques may require high coherence. In some embodiments, the QSIP platform may address coherence, optical losses, quantum efficiency, state tomography, and readout in lab-scale experiments, which may allow for a real-time, sensitive smart grid monitoring system for early detection of grid issues. Hardware primitives to implement the quantum entanglement protocol

In some embodiments, the QSIPs may be used to develop a secure, entangled quantum smart grid network, such as by leveraging quantum entanglement to enhance sensing, including beyond classical limits. In some embodiments, communication may be established over classical grids. In some embodiments, communication may be established through quantum layers, such as for heightened security, which may include the use of encryption and quantum key distribution. In some embodiments, a fully entangled quantum grid with improved sensitivity and resilience may be provided using the QSIP platform. In some embodiments, the QSIP platform may be integrated with existing optical fiber infrastructure for signal transduction, such as into telecom bands.

In some embodiments, one or more of the following two transduction approaches may be used, which may have been shown to yield high conversion efficiencies, and both of which may also be useful for integrating quantum sensors onto an entangled grid.

Four-Wave Mixing (FWM): FWM may be a nonlinear process for frequency conversion, which may broaden the bandwidth for converting NV emissions to communication wavelengths (e.g., 1310 nm, 1550 nm). It may be used to generate generating entangled photon pairs, which may be essential for quantum communication networks—in some embodiments, FWM may be observed with efficiencies up to 35% in SiN microring resonators—and may have the potential to optimize designs. In some embodiments, with the QSIP FWM may be used to generate entangled photon pairs, including combining a degenerate photon pair from stimulated emission with a non-degenerate signal and idler pair. In some embodiments, FWM, such as guided by application of the nonlinear Schrödinger equations (NLSE), may enable the production of non-degenerate entangled photon pairs. For example, equations 1-3 may be used, as follows:

$$i \frac{\partial {A}_{1}}{\partial z} + {β}_{1} \frac{\partial {A}_{1}}{\partial t} + γ {\vert {A}_{1} \vert}^{2} {A}_{1} + γ {\vert {A}_{2} \vert}^{2} {A}_{1} + γ {\vert {A}_{3} \vert}^{2} {A}_{1} = - i {α}_{1} {A}_{1} \qquad ( 1 )$$

$$i \frac{\partial {A}_{2}}{\partial z} + {β}_{2} \frac{\partial {A}_{2}}{\partial t} + γ {\vert {A}_{2} \vert}^{2} {A}_{2} + γ {\vert {A}_{1} \vert}^{2} {A}_{2} = - i {α}_{2} {A}_{2} \qquad ( 2 )$$

$$i \frac{\partial {A}_{3}}{\partial z} + {β}_{3} \frac{\partial {A}_{3}}{\partial t} + γ {\vert {A}_{3} \vert}^{2} {A}_{3} + γ {\vert {A}_{1} \vert}^{2} {A}_{3} = - i {α}_{3} {A}_{3} \qquad ( 3 )$$

Where A₁, A₂, and A₃ represent the slowly varying envelope of the degenerate pump corresponding to the stimulated emission of the diamond NV center (ω₁), non-degenerate signal field (at ω₂) and the non-degenerate idler field (at ω₃), respectively. The propagation distance along the fiber may be given by z, while t is time and (β₁, β₂, β₃) may represent the group velocities of the fields, γ is the nonlinear coefficient and α₁, α₂, α₃ may represent linear losses. In some embodiments, these equations may describe the interaction between the degenerate pump and the quantum entangled non-degenerate signal and idler pair, which may generated from the FWM process.

Difference Frequency Generation (DFG): DFG may be a three-wave mixing nonlinear optical process, which may be useful for transduction in quantum networking. In some embodiments, by combining photons of different frequencies using periodically poled lithium niobate (PPLN), DFG may be used to convert NV center emissions from 637 nm to communication wavelengths, such as 1310 nm and 1550 nm, which may offer up to 73% efficiency, while preserving single-photon properties, which may be useful for quantum communication. Both FWM and DFG may convert NV center emissions to near infrared (NIR) wavelengths, with the choice between various methods and wavelengths hinging on efficiency, bandwidth, and spectral purity (including operation parameters of other QSIP components). DFG may provide increased conversion efficiency, while FWM may provide wider bandwidth and increased potential for multi-photon entanglement. In some embodiments, both methods may be used, including by different components in the QSIP platform. In some embodiments, integration of multiple components into a compact chip, such as the QSIP platform, may involve challenges such as maintaining quantum coherence and ensuring phase matching. In some embodiments, these challenges may be addressed by optimizing design for photon interaction, selecting materials to minimize loss, and developing thermal management to protect qubit integrity.

### Quantum System Integration and Packaging

In some embodiments, the QSIP platform may include a heterogeneously integrated, scalable interposer packaging architecture with a directional quantum interlink, which may merge functionalities within a chip and while maintaining qubit coherence. In some embodiments, the QSIP platform may enhance the interconnect ecosystem by optimizing power, performance, area, mechanical stability, and integration of thermal dissipating materials. In some embodiments, the QSIP platform may also accommodate multiple power domains and a versatile test capability. In some embodiments, the QSIP platform may be suitable for integrating components into a multifunctional quantum sensor system, for example, as described in reference to FIG. 5. In some embodiments, the QSIP platform may the gap(s) between laboratory demonstrations and scalable quantum applications, and many include advantageous features for a modular quantum system.

The QSIP platform may provide for one or more of the advantages (e.g., over classical sensors and platforms) listed below:
In some embodiments, isolation and materials engineering may be used to enhance quantum coherence times, which may be crucial for complex quantum algorithms and sensitive measurements.
In some embodiments, electric field control mechanisms around NV center diamond sensors may serve minimize charge noise and maximize sensing accuracy.
In some embodiments, integrated photonic structures may improve NV centers' optical properties, which may boost qubit readout fidelity and noise isolation.
In some embodiments, chip-scale optical isolators using 2D materials may be deployed within the QSIP platform, which may reduce back-reflection and noise interference.
In some embodiments, scalable quantum sensor arrays, which may have been previously used in only lab-scale academic experiments, may be transformed into robust, deployable field sensors.
In some embodiments, integration of quantum error correction schemes within QSIP may provide for robust quantum information integrity.
In some embodiments, the QSIP platform may provide quantum sensor networks capable of secure, long-range information transfer, which may be useful for a future quantum internet.
In some embodiments, the QSIP may provide security through generation and distribution of quantum entanglement across network nodes, such as facilitated by Quantum Key Distribution (QKD).
In some embodiments, the QSIP network may provide incorporation of quantum repeaters to expand the range of quantum communication networks.
In some embodiments, the QSIP platform may provide fiber-optic I/O for integration into quantum networking.
In some embodiments, alternate interposers such as diamond in QSIP for enhanced thermal and electronic properties may be used to support higher temperature operation.
In some embodiments, nanofabrication techniques may be used for precise placement of quantum components, including at the nanoscale, which may enhance scalability.
In some embodiments, integration of diverse material systems onto a single QSIP platform may allow for creation of a universal, material-agnostic approach to quantum technology.

In order to address patterning, integration, and assembly complexities, especially as more quantum sensors are added, in various embodiments, the QSIP may be designed to overcome thermal, electromagnetic, and other isolation challenges. In some embodiments, the QSIP platform may include packaging for optical and electrical I/O, for which silicon may be chosen for its design and fabrication advantages and low microwave dielectric loss, which allows for provision of electromagnetic interference isolation. For interconnection of each component, in some embodiments, chiral (e.g., directional or nonreciprocal) interconnect may be used for both for electrical and optical interconnects. For low temperature electric and microwave interconnects, a dissipation-less chiral quantum anomalous Hall effect may be used to provide for electrical signals to Ru. For microwave interconnects at room temperature, reciprocal element of YIG may be used instead or additionally to minimize the reflected noises. Likewise, for optical interconnect, in some embodiments, chiral photonic crystals may be used, which may include the use of the quantum anomalous Hall to pattern a photonic crystal with a ferromagnetic insulator such as YIG, so that optical transport may have minimized noise from the external and reflected sources. In some embodiments, one or more of these interconnect strategies may be used to integrate devices like diamond NV sensors and atomic clocks onto silicon substrates, including by employing physical integration processes like through-silicon vias (TSVs) fabrication and bonding techniques such as electrostatic or metal-to-metal fusion bonding. In some embodiments, a final packaging stage may involve wire bonding, fiber connections, and housing use for thermalization and electromagnetic shielding.

In some embodiments, the QSIP platform integration may provide advantages (e.g., over classical systems, current grid monitoring networks, etc.) which may include one or more of the following:

Heterogeneous quantum system integration, which may involve combining various quantum devices—such as diamond NV centers, cesium atom clocks, and single-photon sources—using interposer technology, which may allow for integration which focusses on thermal and operational integrity.

Thermal and mechanical isolation engineering, which may be facilitated by the development and use of materials and methods for thermal isolation on interposers, which may in turn stabilize quantum states, while also ensuring mechanical integrity across diverse devices.

Optical low loss interconnects and quantum clock synchronization, which may allow for establishment of efficient communication channels and synchronization protocols for NV centers, transducers, atom clocks, photon sources, and other components, which may be crucial for operational coherence in quantum computing and sensing devices.

Quantum packaging and microfabrication, which may use microfabrication for dense 2.5D/3D integration, which may in turn be vital for constructing multi-qubit arrays and distributing entanglement. In some embodiments, packaging and microfabrication may include vertical interconnect access technologies for layering quantum circuits and maintaining quantum coherence.

Quantum reliability in packaging, which may integrate quantum interconnects within QSIP or component packaging in order to preserve coherence and entanglement. In some embodiments, through design and testing protocols optimal system performance in multi-layered processors may be achieved.

While, in some embodiments, while the QSIP platform's primary application may be on smart grid monitoring, it may also have application for quantum cryptography and precision metrology.

### Quantum Sensing for Smart Grid Application

In some embodiments, the QSIP platform may focuses on integration and deployment of quantum sensors for grid-relevant conditions, which may be interrogated via a fiber optic network for precise current monitoring. In some embodiments, measurements under 1 μs with atomic clock synchronization and rapid quantum networking (over 120 samples per second) are provided for. In some embodiments, QSIP sensors may provide for transient current anomaly detection in power transformers. In some embodiments, these sensors, which may be robust against electromagnetic interference, may offer advanced monitoring beyond current technology. For example, an NV-diamond sensor array may visualize operational power transformers, in a manner analogous to magnetoencephalography (MEG) brain imaging. Moreover, enhancing a phasor measurement unit (PMU) accuracy for grid modernization and DER integration may be provided by the QSIP platform and may be valuable, especially for constant angular frequency and sinusoidal conditions. In some embodiments, the QSIP platform and associated sensors may measure AC current-associated magnetic fields to enable accurate, real-time grid operation and synchronization assessments.

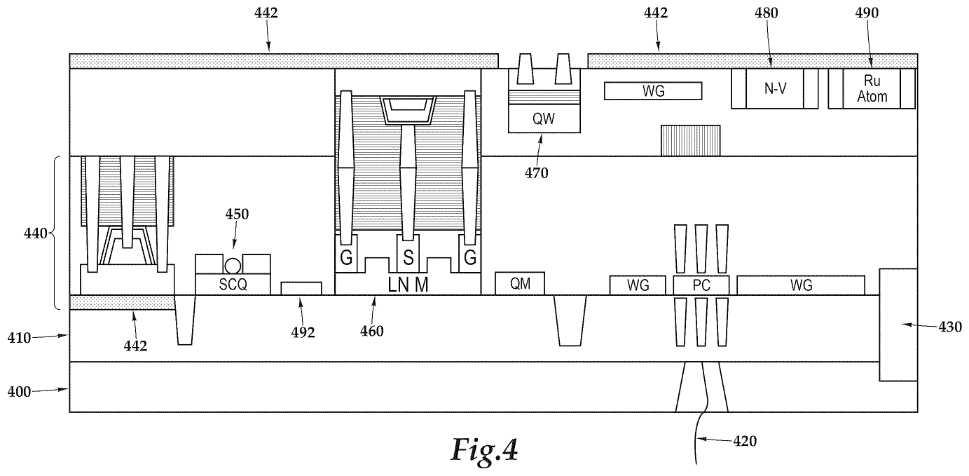

FIG. 4 is a schematic representation of a cross-sectional view of an example QSIP platform. FIG. 4 is provided as an example illustration, and the QSIP platform may contain more or fewer chips, elements, etc. The QSIP may contain or be multiple chips. In the illustrated example of FIG. 4, the QSIP is built on a silicon layer 400 (or substrate), which is topped with an insulating layer 410 of silicon dioxide, but which may be any appropriate substrate and passivation layer, including buried silicon dioxide, Ge, GaAs, SiN, etc. The QSIP may include one or more input and output mechanism, which may include a backside optical I/O 420, depicted as a coupler with a pig tail, an optical I/O edge coupler 430, frontside optical couplers (not depicted), or any other appropriate I/O devices, including optical, electronic, microwave, etc. input and output mechanisms. The QSIP may include multiple chips, which may be integrated homogeneously, e.g., during fabrication, to the QSIP, or heterogeneously integrated, such as through flip-chip bonding, TSVs, etc. to the QSIP as discrete chips. For example, the QSIP may include an electronics chip 440, which may be in contact with one or more metal heat sink 442, including a metal heat sink incorporated into the QSIP insulating layer (e.g., insulating layer 410). The QSIP may include one or more superconducting qubit, such as superconducting qubit 450. The superconducting qubit may be any appropriate qubit, and may have any appropriate associated heating, cooling, or other electronic control systems, either incorporated into the chip containing the superconducting qubit 450 or into the QSIP, including surrounding the superconducting qubit 450. The QSIP may include one or more modulator, e.g., one or more electo-optical modulator, such as a lithium niobate modulator (LNM) 460. The modulator may be any appropriate modulator. The QSIP may include one or more optical (e.g., photonic) source. For example, the QSIP may include a single photon light source 470, laser, or any other appropriate photonic source of any appropriate type and with any appropriate wavelength. The single photon light source 470 may contain one or more quantum well (QM). The QSIP may include one or more optical (e.g., photonic) detector. For example, the QSIP may include a quantum Raman gain laser sensor and transducer 480, or any other appropriate photodetector, photosensor, opto-electronic transducer, etc. The QSIP may include one or more clock (e.g., timing device). In some embodiments, the clock may be an atomic clock, such as previously described. In FIG. 4, the clock is depicted as a Ru atomic clock, which may have associated timing circuitry, transducer circuitry, etc. The QSIP may include further electronic, optical, and other appropriate circuitry, such as one or more waveguides WG, one or more photonic crystal PC, one or more 2D electrical interconnect 492, one or more quantum memory QM, other passive and active photonic devices, one or more heat sinks 442, etc. The QSIP as depicted in FIG. 4 is provided for an illustrative example, and in some embodiments, the QSIP may include more or fewer elements, including additional processing, memory, peripheral circuitry, sensors, etc. The QSIP may allow discrete elements to function as a platform through integration, including through packaging integration.

FIG. 5 is a schematic representation of an angle view of an example QSIP platform with chip bonding. The QSIP platform in FIG. 5 is provided as an illustrative example, and contains a NV quantum Raman gain laser with integrated sensor and a transducer 502; directional interconnects 504 with chiral circulators; photonic interconnects 506 such as waveguides, metamaterial couplers, or any other appropriate photonic interconnects; optical fiber I/O interconnects 508; flip chip bonded atomic clock 510 or other clocking circuits, which may be attached with bump bonds; silicon interposer 512, which may be compatible with quantum qubits, SiPh components, V-grooves for fiber I/O, or any other components as described herein; printed circuit board (PCB) 514 with peripheral circuits; and on-chip microwave circuits 516. In some embodiments, the interposer material may be silicon, sapphire, or any other appropriate material. The QSIP may have an efficient, low loss, small footprint (such as five times smaller than a conventional transducer) quantum transducer on a SiN or diamond platform. In some embodiments, the qubit (e.g., the NV qubit in the NV quantum Raman gain laser with integrated sensor and a transducer 502) may be controlled by circuitry integrated into the interposer 512 or PCB 514, such as through TSVs.

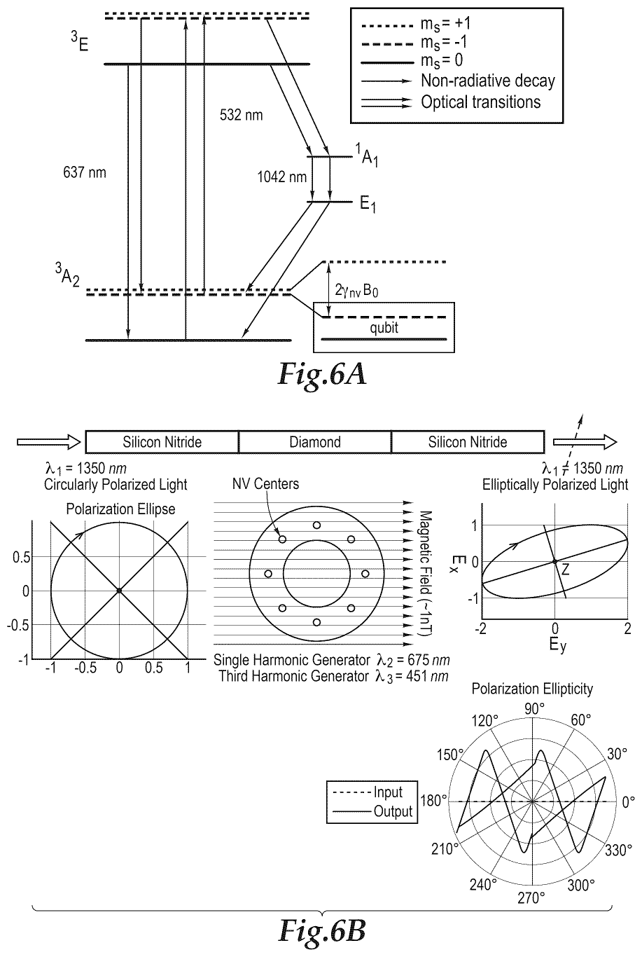

FIG. 6A is an example energy band diagram for photons in the NV center. FIG. 6A depicts the example energy band for the photons of an NV qubit in a magnetic field B, where the degenerate energy levels are split by the magnetic field, as was also depicted in reference to FIG. 2A.

FIG. 6B is a schematic diagram for an example quantum Raman sensor and transducer for use with a QSIP platform. FIG. 6B depicts circularly polarized light input into a silicon nitride waveguide, with input light having a wavelength 1350 nm, and transmitted to a diamond waveguide or other diamond photonic device for interaction with one or more NV center within the magnetic field B, which may have strength approximately equal to 1 nT. In some embodiments, the input light may be any appropriate light, such as photons in the O-band (e.g., from substantially 1260 to 1360 nm) or the C-band (e.g., from substantially 1530 nm to 1565 nm) or any other appropriate telecommunication wavelength. From the NV center, the output light is transmitted to a silicon nitride waveguide and a detector, where the ellipticity of the polarization in the output light is measured. As described in relation to FIG. 2B, from such a relationship, the applied magnetic field may be determined, where the output polarization is a function of the applied magnetic field.

NV centers may generate photons as the single harmonic generator (SHG) at 675 nm, or the third harmonic generator (THG) at 450 nm—that is, such light may be generated inside the ring resonator at the NV centers from the input light at 1350 nm. The generated SHG photons are polarization sensitive, and therefore alter the polarization (e.g., ellipticity of polarization) of the light which passes through them. Further, the SHG photons may simulate the diamond NV center transition, which may occur around 637 nm, and which may then be amplified by Raman lasing in the diamond resonator. Therefore, small perturbations in the magnetic field, such as on the order of nT, may change the behavior of the diamond NV center qubits, where such change may be detected through optical polarization changes.

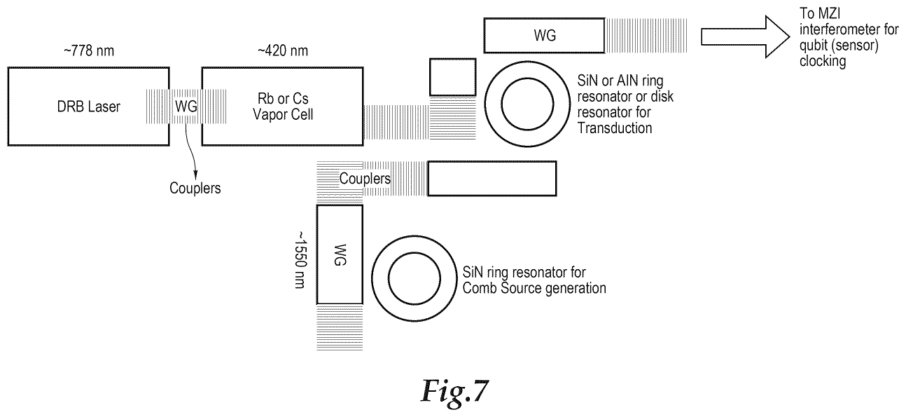

FIG. 7 is a schematic representation of an atomic clock for qubit synchronization and timing control for use with a QSIP platform. The atomic clock may be driven by a distributed Bragg reflector (DBR) laser, or any other appropriate photon (e.g., laser) source. The atomic clock may be any appropriate atomic clock, such as described in relation to FIG. 3. The atomic clock may contain a vapor cell, such as a Rb or Cs or any other appropriate vapor molecule cell. The vapor cell may include heater or other vaporization elements, such as to maintain the presence of vapor in the vapor cell. The vapor cell may be coupled, such as by one or more optical couplers or other coupling element to a waveguide. The frequency or wavelength of the atomic clock may be any appropriate frequency or wavelength, such as determined by the element contained within the vapor cell or any other configuration of the atomic clock. As depicted in FIG. 7, a signal from the atomic clock, may be coupled to a resonator for transduction, such as to an SiN or AlN ring or disk resonator, or any other appropriate resonator geometry or material. The signal may then be fed to a Mach-Zehnder interferometer (MZI) for qubit or other sensor clocking. As depicted in FIG. 7, a signal from the atomic clock may also or instead be coupled to a SiN ring resonator (or resonator of any other appropriate geometry or material) for Comb source generator or other harmonic generation. A pair of micro resonator frequency combs may serve as optical clockwork.

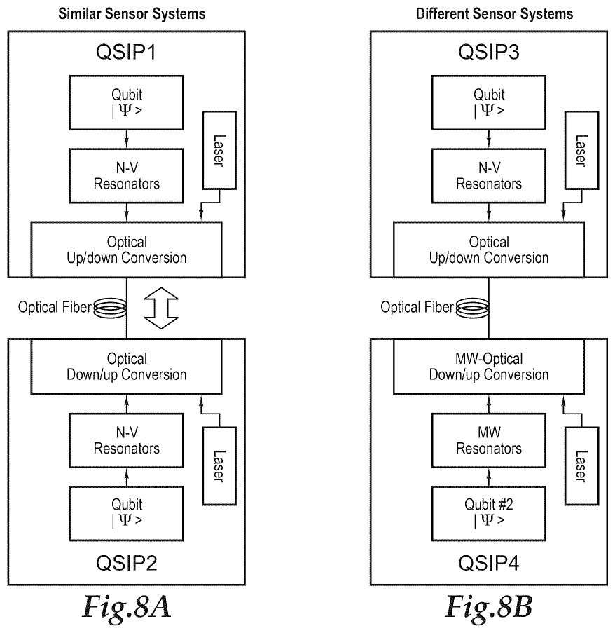

FIG. 8A-8B are schematic representations of interfacing between distributed quantum systems for use with a QSIP platform. FIG. 8A is a schematic representation of interfacing between similar sensing systems. For similar sensing systems, such as QSIP1 and QSIP2, each QSIP may contain one or more qubit(s) in communication with one or more NV resonator(s). The signal output by the NV resonator(s) may be processed by optical up/down conversion circuitry, which may in turn be driven by one or more laser(s) or other optical source. The optical up-down conversion circuitry may operate to convert the optical (or microwave) signal emitted by the qubit, in some embodiments, or the NV center, in some embodiments, to a telecommunication wavelength for transmission across one or more optical fiber(s), such as for transmission from QSIP1 to QSIP2 and vice versa.

FIG. 8B is a schematic representation of interfacing between different sensing systems. For different sensing systems, such as QSIP3 and QSIP4, each NV center QSIP, such as QSIP3, may contain one or more qubit(s) in communication with one or more NV resonator(s). The signal output by the NV resonator(s) may be processed by optical up/down conversion circuitry, which may in turn be driven by one or more laser(s) or other optical source. The optical up-down conversion circuitry may operate to convert the optical (or microwave) signal emitted by the qubit, in some embodiments, or the NV center, in some embodiments, to a telecommunication wavelength for transmission across one or more optical fiber(s), such as for transmission from QSIP3 to QSIP4 and for conversion of a telecommunication wavelength signal received from QSIP4 into an optical wavelength which may be read by the QSIP3.

Each non-NV center QSIP, such as QSIP4, may contain one or more qubit(s) in communication with one or more microwave (MW) resonator(s). The signal output by the MW resonator(s) may be processed by MW up/down conversion circuitry. The MW up-down conversion circuitry may operate to convert the microwave signal emitted by the qubit, in some embodiments, to a telecommunication wavelength for transmission across one or more optical fiber(s), such as for transmission from QSIP4 to QSIP3 and for conversion of a telecommunication wavelength signal received from QSIP3 into an MW wavelength which may be read by the QSIP4.

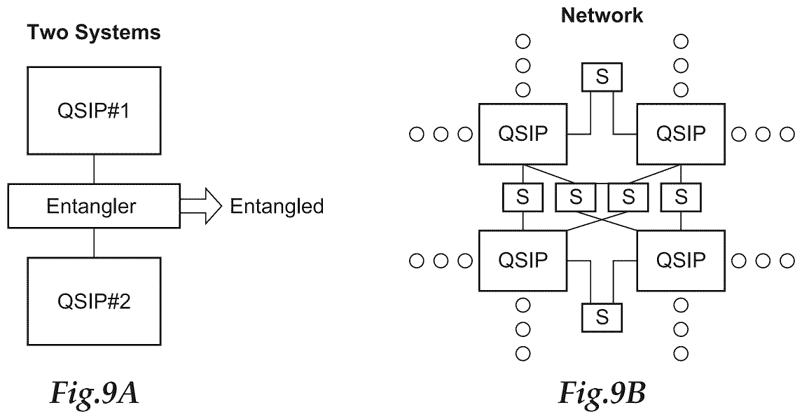

FIG. 9A is a schematic representation of entanglement between two different QSIP platform. In some embodiments, qubits held (e.g., which exist in) in different QSIPs, e.g., QSIP #1 and QSIP #2, may be entangled by an entangler. The entangler may be any appropriate entangler, such as an entangler of an optical qubit, spin qubit, etc. The entangler may be a function of the qubits of the QSIPs—that is, the qubit of QSIP #1 and the qubit of QSIP #2 may be entangled, such as as fabricated, as controlled, etc. The entangler may generate a one-way entanglement. The entangler may generate a two-way entanglement. The entangler may generate a multi qubit entanglement. The entangler may be a function of the storage of the qubit and may be measurable at either of the QSIPs. The entangled qubits may be any appropriate entangled qubits.

FIG. 9B is a schematic representation of a quantum sensor network using one or more QSIP platform(s). The quantum sensing network may be constructed of various sensors S, which may be any appropriate sensors including classical sensors, quantum sensors, etc. The quantum sensing network may also contain various QSIPs. Each sensor may be associated with one or more grid or other component to be monitored. Each QSIP may be in communication with one or more sensor(s) S. The QSIPs (or various sensors thereof) may be in communication with each other and other grid monitoring equipment, including by quantum entanglement, classical communication, or any other appropriate method.

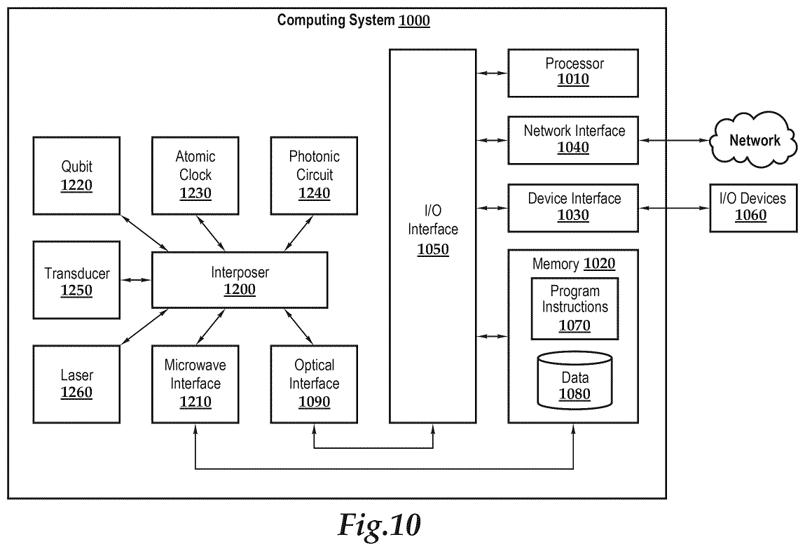

FIG. 10 is a schematic representation of an example computing system for use with a QSIP platform, in accordance one or more embodiments. FIG. 10 is a diagram that illustrates an exemplary computing system 1000 in accordance with embodiments of the present disclosure. Various portions of systems and methods described herein may include or be executed on one or more computing systems similar to computing system 1000. Further, processes and modules described herein may be executed by one or more processing systems similar to that of computing system 1000.

Computing system 1000 may include one or more processor 1010 coupled to system memory 1020, an input/output I/O device interface 1030, an interposer 1200, and a network interface 1040 via an input/output (I/O) interface 1050. A processor 1010 may include a central processing unit (CPU) that carries out program instructions to perform the arithmetical, logical, and input/output operations of computing system 1000. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 1020). Multiple optical logical circuit may be employed to provide for parallel or sequential execution of one or more portions of the techniques described herein. Processes, such as logic flows, described herein may be performed by one or more optical logical circuit executing one or more computer programs to perform functions by operating on input data and generating corresponding output. Processes described herein may be performed by, and apparatus may also be implemented as, special purpose logic circuitry, e.g., an FPGA (field programmable gate array) or an ASIC (application specific integrated circuit). Computing system 1000 may include a plurality of computing devices (e.g., distributed computing systems) to implement various processing functions. The processor 1090 may be a quantum processor, an optical processor, an electronic processor, etc.

The interposer 1200 may be connected to one or more circuits associated with a quantum sensor, such as a quibit 1220, an atomic clock 1230, a photonic circuit 1240, a transducer 1250, a laser 1260, etc. The interposer 1200 may be connected to different circuits, such as any of those previously described, to more circuits, including multiples of those described herein, etc. The interposer 1200 may communicate with the one or more circuits optically, in microwave, electronically, etc. The interposer 1200 may enable communication between the one or more circuits. The interposer 1200 may enable communication (e.g., by providing waveguides, electronic interconnects, etc.) between the one or more circuits. The interposer 1200 may actively communicate with the one or more circuits, such as by providing an optical source, voltage source, etc. The interposer 1200 may be any appropriate interposer, such as previously described.

I/O device interface 1030 may provide an interface for connection of one or more I/O devices 1060 to computing system 1000. I/O devices may include devices that receive input (e.g., from a user) or output information (e.g., to a user). I/O devices 1060 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. I/O devices 1060 may be connected to computing system 1000 through a wired or wireless connection. I/O devices 1060 may be connected to computing system 1000 from a remote location. I/O devices 1060 located on remote computing system, for example, may be connected to computing system 1000 via a network and network interface 1040. The I/O devices may be quantum devices, optical device, electrical devices, etc.

Optical interface 1090 may provide an interface for connection of one or more optical device to an interposer 1200. Optical interface 1090 may provide an interface between the interposer 1200 and the memory 1020 and the processor 1090. Optical interface 1090 may be configured to coordinate optical traffic between processor 1090, system memory 1020, network interface 1040, I/O devices 1060, other peripheral devices, and/or the interposer 1200. Optical interface 1090 may perform protocol, timing, or other data transformations to convert optical signals from one component (e.g., system memory 1020) into a format suitable for use by another component (e.g., qubit 1220). I/O interface 1050 may provide data signals to optical interface 1090, including for conversion to optical signals.

Microwave interface 1210 may provide an interface for connection of one or more microwave device to the interposer 1200. Microwave interface 1210 may provide an interface between the interposer 1200 and the memory 1020 and the processor 1090. Microwave interface 1210 may be configured to coordinate microwave traffic between processor 1090, system memory 1020, network interface 1040, I/O devices 1060, other peripheral devices, and/or the interposer 1200. Microwave interface 1210 may perform protocol, timing, or other data transformations to convert microwave signals from one component (e.g., transducer 1250) into a format suitable for use by another component (e.g., qubit 1220). I/O interface 1050 may provide data signals to Microwave interface 1210, including for conversion to microwave signals.

Network interface 1040 may include a network adapter that provides for connection of computing system 1000 to a network. Network interface 1040 may facilitate data exchange between computing system 1000 and other devices connected to the network. Network interface 1040 may support wired or wireless communication. The network may include an electronic communication network, such as the Internet, a local area network (LAN), a wide area network (WAN), a cellular communications network, or the like.

System memory 1020 may be configured to store program instructions 1070 or data 1080. Program instructions 1070 may be executable by the processor 1090 to implement one or more embodiments of the present techniques. Instructions 1070 may include modules of computer program instructions for implementing one or more techniques described herein with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 1020 may include a tangible program carrier having program instructions stored thereon. A tangible program carrier may include a non-transitory computer readable storage medium. A non-transitory computer readable storage medium may include a machine-readable storage device, a machine-readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random-access memory (SRAM), synchronous dynamic RAM (SDRAM)), bulk storage memory (e.g., CD-ROM and/or DVD-ROM, hard drives), or the like. System memory 1020 may be quantum system memory, optical system memory, or electronic system memory. System memory 1020 may include a non-transitory computer readable storage medium that may have program instructions stored thereon that are executable by a computer processor (e.g., processor 1090) to cause the subject matter and the functional operations described herein. A memory (e.g., system memory 1020) may include a single memory device and/or a plurality of memory devices (e.g., distributed memory devices). Instructions or other program code to provide the functionality described herein may be stored on a tangible, non-transitory computer readable media. In some cases, the entire set of instructions may be stored concurrently on the media, or in some cases, different parts of the instructions may be stored on the same media at different times.

I/O interface 1050 may be configured to coordinate I/O traffic between processor 1090, system memory 1020, network interface 1040, I/O devices 1060, and/or other peripheral devices. I/O interface 1050 may perform protocol, timing, or other data transformations to convert data signals from one component (e.g., system memory 1020) into a format suitable for use by another component (e.g., optical logical circuits and optical memory circuits). I/O interface 1050 may provide data signals to optical interface 1090, including for conversion to optical signals, such as to supply to optical logical circuits and optical memory circuits. I/O interface 1050 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computing system 1000 or multiple computing systems 100 configured to host different portions or instances of embodiments. Multiple computing systems 100 may provide for parallel or sequential processing/execution of one or more portions of the techniques described herein.

Those skilled in the art will appreciate that computing system 1000 is merely illustrative and is not intended to limit the scope of the techniques described herein. Computing system 1000 may include any combination of devices or software that may perform or otherwise provide for the performance of the techniques described herein. For example, computing system 1000 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computing system 1000 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computing system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computing system 1000 may be transmitted to computing system 1000 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computing system configurations.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computing system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computing system 1000 may be transmitted to computing system 1000 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computing system configurations.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein. In some cases, third party content delivery networks may host some or all of the information conveyed over networks, in which case, to the extent information (e.g., content) is said to be supplied or otherwise provided, the information may be provided by sending instructions to retrieve that information from a content delivery network.

The reader should appreciate that the present application describes several disclosures. Rather than separating those disclosures into multiple isolated patent applications, applicants have grouped these disclosures into a single document because their related subject matter lends itself to economies in the application process. But the distinct advantages and aspects of such disclosures should not be conflated. In some cases, embodiments address all of the deficiencies noted herein, but it should be understood that the disclosures are independently useful, and some embodiments address only a subset of such problems or offer other, unmentioned benefits that will be apparent to those of skill in the art reviewing the present disclosure. Due to cost constraints, some features disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such disclosures or all aspects of such disclosures.

It should be understood that the description and the drawings are not intended to limit the disclosure to the particular form disclosed, but to the contrary, the intention is to cover all modifications, equivalents, and alternatives falling within the spirit and scope of the present disclosure as defined by the appended claims. Further modifications and alternative embodiments of various aspects of the disclosure will be apparent to those skilled in the art in view of this description. Accordingly, this description and the drawings are to be construed as illustrative only and are for the purpose of teaching those skilled in the art the general manner of carrying out the disclosure. It is to be understood that the forms of the disclosure shown and described herein are to be taken as examples of embodiments. Elements and materials may be substituted for those illustrated and described herein, parts and processes may be reversed or omitted, and certain features of the disclosure may be utilized independently, all as would be apparent to one skilled in the art after having the benefit of this description of the disclosure. Changes may be made in the elements described herein without departing from the spirit and scope of the disclosure as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing actions A, B, C, and D) encompasses both all such attributes or functions being mapped to all such objects and subsets of the attributes or functions being mapped to subsets of the attributes or functions (e.g., both all processors each performing actions A-D, and a case in which processor 1 performs action A, processor 2 performs action B and part of action C, and processor 3 performs part of action C and action D), unless otherwise indicated. Further, unless otherwise indicated, statements that one value or action is “based on” another condition or value encompass both instances in which the condition or value is the sole factor and instances in which the condition or value is one factor among a plurality of factors. The term “each” is not limited to “each and every” unless indicated otherwise. Unless specifically stated otherwise, as apparent from the discussion, it is appreciated that throughout this specification discussions utilizing terms such as “processing,” “computing,” “calculating,” “determining,” “solving,” or the like refer to actions or processes of a specific apparatus, such as a special purpose computer or a similar special purpose electronic processing/computing device.

The above-described embodiments of the present disclosure are presented for purposes of illustration and not of limitation, and the present disclosure is limited only by the claims which follow. Furthermore, it should be noted that the features and limitations described in any one embodiment may be applied to any other embodiment herein, and flowcharts or examples relating to one embodiment may be combined with any other embodiment in a suitable manner, done in different orders, or done in parallel. In addition, the systems and methods described herein may be performed in real time. It should also be noted that the systems and/or methods described above may be applied to, or used in accordance with, other systems and/or methods.

In this patent filing, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

The present techniques may be better understood with reference to the following enumerated embodiments:
A1. An interposer comprising:
one or more photonic waveguide;
one or more microwave circuit;
one or more optical interconnect; and
one or more electronic interconnect,
further configured to support a quantum sensor.
A2. The interposer of embodiment A1, further configured to support one or more additional circuits.
A3. The interposer of embodiment A2, wherein the quantum sensor and the one or more additional circuits are integrated into the interposer.
A4. The interposer of embodiment A3, wherein at least some of the quantum sensor and the one or more additional circuits are integrated homogeneously into the interposer.
A5. The interposer of embodiment A3 or A4, wherein at least some of the quantum sensor and the one or more additional circuits are integrated heterogeneously with the interposer.
A6. The interposer of embodiment A2, wherein the one or more additional circuits comprises an atomic clock.
A7. The interposer of embodiment A2, wherein the one or more additional circuits comprises a transducer.
A8. The interposer of embodiment A2, wherein the one or more additional circuits comprises memory and/or a processor.
A9. The interposer of embodiment A2, wherein the one or more additional circuits comprise photonic circuits.
A10. The interposer of embodiment A2, wherein the one or more additional circuits comprise electronic circuits.
A11. The interposer of embodiment A2, wherein the one or more additional circuits comprise microwave circuits.
A12. The interposer of embodiment A2, wherein the interposer is configured to provide electronic isolation between at least some of the quantum sensor and the additional circuits.
A13. The interposer of embodiment A2, wherein the interposer is configured to provide optical isolation between at least some of the quantum sensor and the additional circuits.
A14. The interposer of embodiment A2, wherein the interposer is configured to provide microwave isolation between at least some of the quantum sensor and the additional circuits.
A15. The interposer of embodiment A1, wherein the interposer is fabricated substantially of silicon.
A16. The interposer of embodiment A1, wherein the interposer is substantially mechanically stable.
A17. The interposer of embodiment A1, wherein the quantum sensor comprise a microdiamond Nitrogen Vacancy (NV) center qubit.
A18. The interposer of embodiment A1, wherein the quantum sensor is operable at a temperature substantially equal to room temperature.
A19. The interposer of embodiment A1, wherein at least one optical interconnect comprises an optical interconnect configured to interface with an optical fiber.
A20. A combination of one or more of the interposers of any preceding embodiments.
A21. An array of one or more of any of the interposers of any preceding embodiments.
A22. A method of fabricating the interposer of any embodiment 1-19.
A23. A method of operating the interposer of any of embodiments A1-A19.
B1. A method of operating an sensing network comprising: receiving, by a first sensor, a quantum measurement; causing the quantum measurement at the first sensor to be entangled with a measurable signal at a second sensor; and reading the measurement at the second sensor, wherein the first sensor is supported by an interposer comprising at least a first qubit and wherein the second sensor is supported by an interposer comprising at least a second qubit.

1. An interposer comprising:
one or more photonic waveguide;
one or more microwave circuit;
one or more optical interconnect; and
one or more electronic interconnect,
further configured to support a quantum sensor.

2. The interposer of claim 1, further configured to support one or more additional circuits.

3. The interposer of claim 2, wherein the quantum sensor and the one or more additional circuits are integrated into the interposer.

4. The interposer of claim 3, wherein at least some of the quantum sensor and the one or more additional circuits are integrated homogeneously into the interposer.

5. The interposer of claim 3, wherein at least some of the quantum sensor and the one or more additional circuits are integrated heterogeneously with the interposer.

6. The interposer of claim 2, wherein the one or more additional circuits comprises an atomic clock.

7. The interposer of claim 2, wherein the one or more additional circuits comprises a transducer.

8. The interposer of claim 2, wherein the one or more additional circuits comprises memory and/or a processor.

9. The interposer of claim 2, wherein the one or more additional circuits comprise photonic circuits.

10. The interposer of claim 2, wherein the one or more additional circuits comprise electronic circuits.

11. The interposer of claim 2, wherein the one or more additional circuits comprise microwave circuits.

12. The interposer of claim 2, wherein the interposer is configured to provide electronic isolation between at least some of the quantum sensor and the additional circuits.

13. The interposer of claim 2, wherein the interposer is configured to provide optical isolation between at least some of the quantum sensor and the additional circuits.

14. The interposer of claim 2, wherein the interposer is configured to provide microwave isolation between at least some of the quantum sensor and the additional circuits.

15. The interposer of claim 1, wherein the interposer is fabricated substantially of silicon.

16. The interposer of claim 1, wherein the interposer is substantially mechanically stable.

17. The interposer of claim 1, wherein the quantum sensor comprise a microdiamond Nitrogen Vacancy (NV) center qubit.

18. The interposer of claim 1, wherein the quantum sensor is operable at a temperature substantially equal to room temperature.

19. The interposer of claim 1, wherein at least one optical interconnect comprises an optical interconnect configured to interface with an optical fiber.

20. A method of operating an sensing network comprising:
receiving, by a first sensor, a quantum measurement;
causing the quantum measurement at the first sensor to be entangled with a measurable signal at a second sensor; and
reading the measurement at the second sensor,
wherein the first sensor is supported by an interposer comprising at least a first qubit and wherein the second sensor is supported by an interposer comprising at least a second qubit.
